(19) United States
(12) Patent Application Publication
(10) Pub. No.: US 2020/0288592 A1
(43) Pub. Date: Sep. 10, 2020

(54) DECORATIVE SHEET AND ELECTRONIC DEVICE COVER PLATE

(71) Applicant: Shine Optoelectronics (Kunshan) Co., Ltd., Kunshan City (CN)

(72) Inventor: Yulong Gao, Kunshan (CN)

(21) Appl. No.: 16/880,523

(22) Filed: May 21, 2020

Related U.S. Application Data
(63) Continuation of application No. PCT/CN2018/115345, filed on Nov. 14, 2018.

(30) Foreign Application Priority Data
Nov. 24, 2017 (CN) 201711193958.7

(51) Int. Cl. H05K 5/02; H05K 5/03; B32B 7/12

(52) U.S. Cl. CPC H05K 5/0243; B32B 2451/00; B32B 7/12; H05K 5/03

(57) ABSTRACT

Disclosed is a decorative sheet, comprising: a supporting body (20), the supporting body (20) including a first surface and a second surface opposite to the first surface; a solid film (10), the solid film (10) located on the first surface of the supporting body (20), wherein the solid film (10) has a thickness of no more than 1 μm. In addition, an electronic device cover plate comprising the decorative sheet is also disclosed.

### CROSS REFERENCE TO RELATED APPLICATIONS

The present application is a continuation of International Application No. PCT/CN2018/115345, filed on Nov. 14, 2018, which claims the priority of the Chinese patent application for invention No. 201711193958.7, entitled “Decorative Sheet and Electronic Device Cover Plate”, submitted on Nov. 24, 2017, of which the entire contents are incorporated herein by reference.

### TECHNICAL FIELD

The present invention relates to the technical field of optical film decoration. To be more specific, the present invention relates to a decorative sheet and an electronic device cover plate.

### BACKGROUND

With the development of technology, decorative films are widely used on the surfaces of electronic products such as mobile phones and computers, household appliances such as refrigerators, air conditioners and washing machines, automobiles and other products.

The existing decorative films are used as surface materials for mobile devices such as mobile phones and laptops, and as surface materials for molding use for household appliances such as refrigerators, washing machines, and air conditioners. Decorative sheets are used to present a variety of textures and metal senses by intaglio printing, or, materials such as metals or ceramic are directly used for decoration.

Such decorative materials are costly and will increase the weight of the equipment itself. Therefore, it is necessary to provide a decorative sheet which not only reduces the cost but also plays a role of beautiful decoration to solve the existing technical problem.

### SUMMARY

On this basis, there is a necessity to provide a decorative sheet and an electronic device cover plate to solve the above technical problem.

One technical solution of the present invention is:

A decorative sheet, comprising:

a supporting body including a first surface and a second surface opposite to the first surface;

a solid film located on the first surface of the supporting body, wherein the solid film has a thickness of no more than 1 μm.

In one embodiment, the material of the solid film is one or more of an elementary substance, a metal oxide, a non-metal oxide or an organic material.

In one embodiment, a bonding layer is provided between the supporting body and the solid film.

In one embodiment, the supporting body is one or a combination of two or more of PET, PMMA, PC, a heat-curing adhesive, a light-curing adhesive, organic glass or inorganic glass.

An electronic device cover plate, comprising:

a housing including a user plane and an inner surface opposite to the user plane;

a bonding layer located on the inner surface of the housing;

a solid film located on a side of the bonding layer away from the housing;

a coloring layer located on a side of the solid film away from the bonding layer.

In one embodiment, the solid film has a thickness of no more than 0.8 μm.

In one embodiment, the housing is made of inorganic glass, a composite plate or organic glass.

An electronic device cover plate, comprising:

a housing including a user plane and an inner surface opposite to the user plane;

a decorative sheet including a supporting body and a solid film, the supporting body including a first surface and a second surface opposite to the first surface, the solid film being located on the first surface of the supporting body;

a bonding layer located between the housing and the decorative sheet, the solid film in the decorative sheet facing towards the bonding layer.

In one embodiment, the housing is made of inorganic glass, a composite plate or organic glass.

In one embodiment, there is also a coloring layer, and the coloring layer is located on the second surface of the supporting body; or

the coloring layer is located between the supporting body and the solid film.

### Advantageous Effects of the Present Invention

The present invention provides a decorative sheet and an electronic device cover plate, wherein the plated film layer is put in front to directly adjoin the user plane, so that the appearance of the electronic device is more bright and beautiful, and light reflected by the plated film layer gives the user a sense of nearness in distance.

### BRIEF DESCRIPTION OF THE DRAWINGS

FIG. 1 is a structural diagram of a decorative sheet of the present invention;

FIG. 2 is a structural diagram of an electronic device cover plate of the present invention;

FIG. 3 is a structural diagram of a section along A-A′ in FIG. 2 of the present invention;

FIG. 4 is another structural diagram of the cover plate of the present invention;

FIG. 5 is another structural diagram of the cover plate of the present invention;

FIG. 6 is another structural diagram of the cover plate of the present invention;

FIG. 7 is another structural diagram of the decorative sheet of the present invention;

FIG. 8 is another structural diagram of the decorative sheet of the present invention;

FIG. 9 is another structural diagram of the decorative sheet of the present invention;

FIG. 10 is another structural diagram of the cover plate of the present invention.

### DETAILED DESCRIPTION

To facilitate understanding of the present invention, a more comprehensive description of the present invention will be given in the following with reference to the relevant accompanying drawings. The accompanying drawings provide preferred embodiments of the present invention. However, the present invention can be implemented in many different forms and is not limited to the embodiments described below. In contrast, the purpose of providing these embodiments is to enable a more thorough and comprehensive understanding of the disclosure of the present invention.

Unless otherwise defined, all technical and scientific terms used herein have the same meaning as commonly understood by technical persons pertaining to the technical field of the present invention. The terms used in the Description of the present invention are for the purpose of describing the specific embodiments only, and are not intended to limit the present invention. The term “and/or” used herein includes any and all combinations of one or more of the relevant listed items.

The present invention provides a decorative sheet that can be used on 3C products and white household appliances to play a decorative role, the decorative sheet comprising a supporting body and a solid film.

The supporting body includes a first surface and a second surface opposite to the first surface. The supporting body may be one or a combination of two or more of PET, PMMA, PC, a heat-curing adhesive, a light-curing adhesive, organic glass or inorganic glass, and a surface of the supporting body itself may be provided with a Hard Coat, a bonding layer, etc.

The solid film is located on the first surface of the supporting body, wherein the solid film has a thickness of no more than 1 μm and can be formed by e-beam evaporator, sputtering, ion plating, physical deposition, chemical deposition, or other methods capable of forming a film layer, in other words, no matter how the solid film is formed, as long as a film layer is formed and has a similar function, it is the same as the solid film. The material used for the solid film may be one or more of an elementary substance, a metal oxide, a non-metal oxide or an organic material. The materials cannot be enumerated one by one here, and any material is applicable as long as it can achieve the decorative effect.

In one embodiment, a bonding layer is provided between the supporting body and the solid film, and the bonding layer can realize bonding of the solid film onto the supporting body; or, in a case where the adhesion between the solid film and the supporting body is not good, a bonding layer is additionally provided on a surface of the supporting layer to enable a better connection of the solid film with the supporting body.

In one embodiment, a coloring layer may also be provided on the second surface of the supporting body. The coloring layer may also be called a base layer. The coloring layer or base layer may be ink, dye materials, coloring materials, etc., and mainly serves the function of shading, shielding or coloring.

The present invention also provides an electronic device cover plate comprising a housing, a bonding layer, a solid film and a coloring layer.

The housing includes a user plane and an inner surface opposite to the user plane, wherein the housing may be made of inorganic glass, a composite plate or organic glass.

The bonding layer is located on the inner surface of the housing for connecting a solid film to the housing. The bonding layer may be water-based glue, may be optical cement, and may also be an OCA adhesive.

The solid film is located on a side of the bonding layer away from the housing. The solid film has a thickness of no more than 0.8 μm. Traditional solid films are disposed far away from the housing, but the solid film in the present invention is placed in front to be closer to the housing so that more gorgeous visual effect is achieved. The solid film not only has the function of reflection, but also allows colors to show, so that the electronic device cover plate is more colorful.

The coloring layer is located on a side of the solid film away from the bonding layer. The coloring layer may also be called a base layer. The coloring layer or base layer may be ink, dye materials, coloring materials, etc., and mainly serves the function of shading, shielding or coloring.

Another structure provided by the present invention is an electronic device cover plate comprising a housing, a decorative sheet, and a bonding layer.

The housing includes a user plane and an inner surface opposite to the user plane, wherein the housing may be made of inorganic glass, a composite plate or organic glass.

The decorative sheet includes a supporting body and a solid film. The supporting body includes a first surface and a second surface opposite to the first surface, the solid film is located on the first surface of the supporting body, and the supporting body may be one or a combination of two or more of PET, PMMA, PC, organic glass or inorganic glass.

The bonding layer is located between the housing and the decorative sheet, and the solid film in the decorative sheet faces towards the bonding layer. The bonding layer is used for connecting the decorative sheet to the housing, and the bonding layer may be water-based glue, may be optical cement, and may also be an OCA adhesive.

In one embodiment, there is also a coloring layer which is located on the second surface of the supporting body, or which is located between the supporting body and the solid film. The coloring layer may also be called a base layer. The coloring layer or base layer may be ink, dyeing materials, coloring materials, etc., and mainly serves the function of coloring, shading and shielding.

Please refer to FIG. 1, which illustrates a decorative sheet comprising a supporting body 20 and a solid film 10. The supporting body 20 includes a first surface and a second surface opposite to the first surface, the solid film 10 is located on the first surface of the supporting body 20. The supporting body 20 may be one or a combination of two or more of PET, PMMA, PC, organic glass or inorganic glass. The solid film 10 is a metal plated film layer or an oxide plated film layer.

Of course, the decorative sheet may also be provided with a coloring layer (not shown in FIG. 1) which is located on the second surface of the supporting body 20, or which is located between the solid film 10 and the supporting body 20.

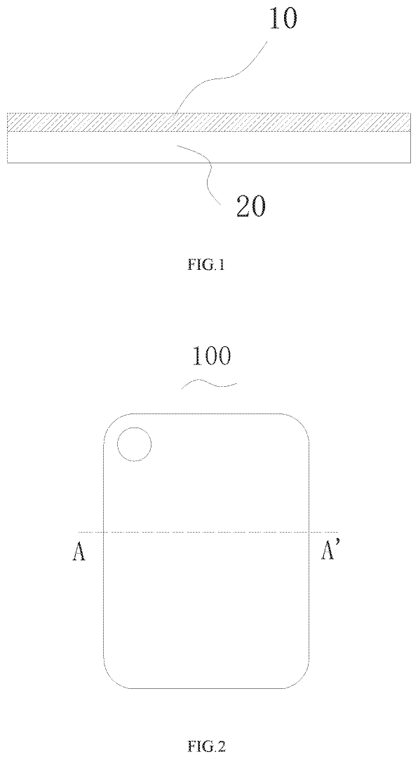

Please refer to FIGS. 2 and 3. FIG. 2 shows a plan view of an electronic device cover plate 100, and FIG. 3 is a sectional view of A-A′ direction in FIG. 2. An electronic device cover plate 100 is provided, comprising a housing 40, a bonding layer 30 and a solid film 10. The housing 40, the bonding layer 30 and the solid film 10 are disposed to be laminated. A coloring layer (not shown in the figures) are provided on a side of the solid film 10 away from the bonding layer 30, wherein the housing 40 may be made of inorganic glass, PMMA, organic glass or a composite plate. Optical cement, OCA adhesives or other adhesives having a bonding effect can be used as the bonding layer 30. The material of the solid film 10 may be Si, Al, SiO2 or other materials.

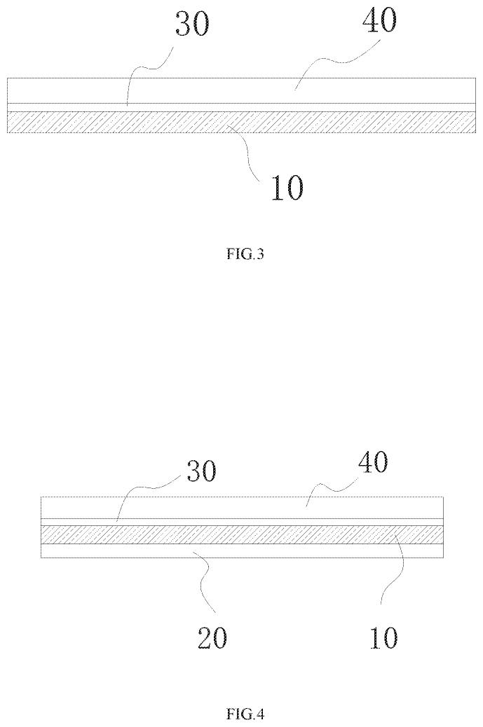

Please refer to FIG. 4, which illustrates a sectional structure of another electronic device cover plate. Provided is an electronic device cover plate 100, comprising a housing 40, a bonding layer 30, a solid film 10 and a supporting body 20. The housing 40, the bonding layer 30, the solid film 10 and the supporting body 20 are disposed to be laminated. In addition, a coloring layer (not shown in the figure) is provided on a side of the supporting body 20 away from the solid film 10 and/or a coloring layer (not shown in the figure) is provided between the solid film 10 and the supporting body 20.

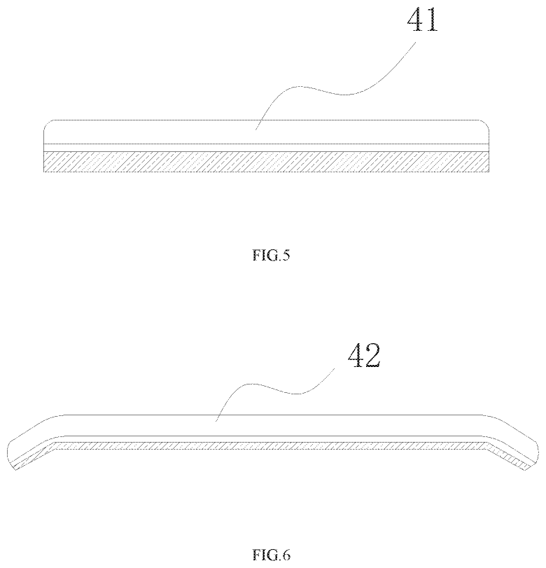

Please refer to FIGS. 5 and 6, which provide a sectional structure of another electronic device cover plate. The housing of the electronic device cover plate is marked by 41 in FIG. 5, in which the edge of the user plane has a certain radian, and the inner surface is a one-dimensional plane. The housing 42 given in FIG. 6 is a housing in which both the user plane and the inner surface have a certain radian or angle. In this way, the electronic device cover plates are more diversified.

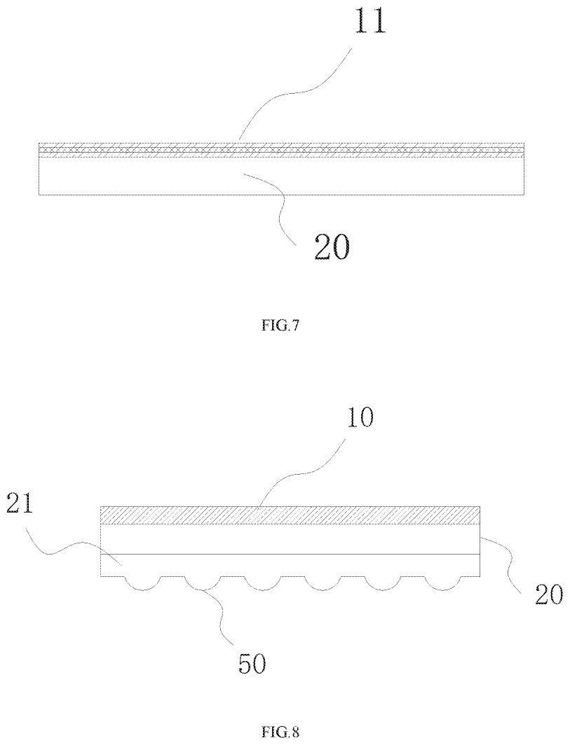

Please refer to FIG. 7, which provides a sectional view of a decorative sheet of another structure. The solid film 11 in FIG. 7 is a multi-layer structure. The solid film 10 in FIG. 1 is a one-layer structure, while the solid film 11 in FIG. 7 is a three-layer structure. The three layers are collectively referred to as a solid film. For both the solid film 10 in FIG. 1 and the solid film 11 in FIG. 7, a refractive index difference between at least one layer of the solid film and the supporting body 20 is not less than 0.3, or not less than 0.25.

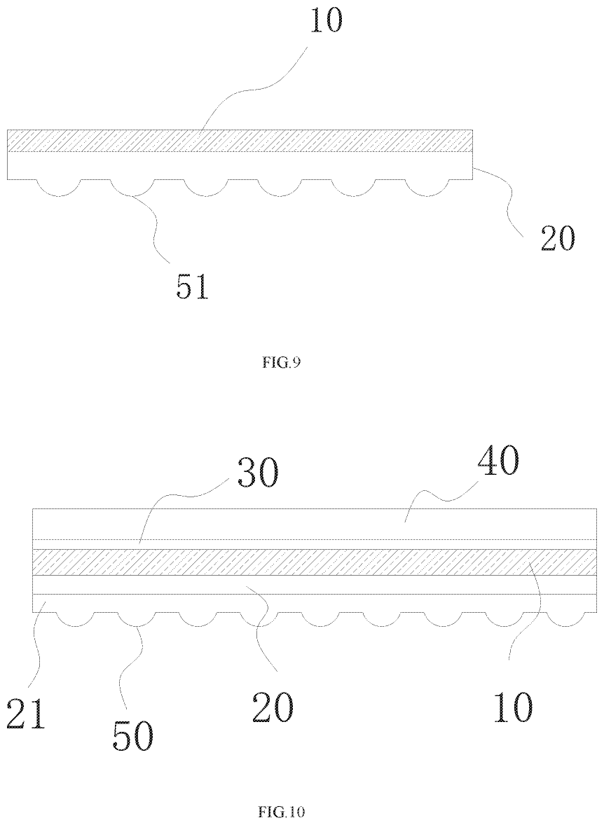

Please refer to FIG. 8, which provides a sectional view of a decorative sheet of another structure. On the basis of FIG. 1, a polymer layer 21 is provided on the second surface of the supporting body 20, and a micro-nano structure 50 is provided on a side of the polymer layer 21 away from the supporting body 20, wherein the micro-nano structure 50 may be one or a combination of several of a cylindrical lens, a micro lens, a Fresnel lens, a CD pattern, a brushed pattern, and a groove. In addition, a reflective layer and a coloring layer (not shown in the figure) may also be provided in sequence on a side of the micro-nano structure 50. Please refer to FIG. 9, which provides a sectional view of a decorative sheet of another structure. In this case a micro-nano structure 51 is directly provided on the second surface of the supporting body 20. The micro-nano structure 51 in FIG. 9 is the same as the micro-nano structure in FIG. 8, and can also be provided with a reflective layer and a coloring layer (not shown in the figure).

Please refer to FIG. 10, which provides a structural diagram of a section of another electronic device cover plate. On the basis of FIG. 4, a polymer 21 is provided on the second surface of the supporting body 20, and a micro-nano structure 50 is provided on a side of the polymer 21 away from the supporting body 20. The micro-nano structure 50 may be one or a combination of several of a cylindrical lens, a micro lens, a Fresnel lens, a CD pattern, a brushed pattern, and a groove. In addition, a reflective layer and a coloring layer (not shown in the figure) may also be provided in sequence on a side of the micro-nano structure 50.

The present invention provides a decorative sheet and an electronic device cover plate, wherein the plated film layer is put in front to directly adjoin the user plane, so that the appearance of the electronic device is more bright and beautiful, and light reflected by the plated film layer gives the user a sense of nearness in distance.

In order to make the above-mentioned objects, features, and advantages of the present invention more obvious and comprehensible, specific embodiments of the present invention have been described in detail in the above with reference to the accompanying drawings. Many specific details have been set forth in the above description for full understanding of the present invention. However, the present invention can be implemented in many other ways different from those described above, and those skilled in the art can make similar improvements without departing from the connotation of the present invention. Thus, the present invention is not limited by the specific embodiments disclosed above. In addition, the technical features of the embodiments described above can be arbitrarily combined. In order to make the description concise, not all possible combinations of the technical features of the above embodiments are described. However, as long as there is no contradiction in the combinations of these technical features, the combinations should be regarded as being within the scope of disclosure contained in this Description.

The above-mentioned embodiments are only several embodiments of the present invention. Although the depictions thereof are specific and detailed, they cannot be understood as limiting the patent scope of the present invention. It should be pointed out that, for ordinary skilled persons in the art, they can also make many deformations and modifications without departing from the concept of invention of the present invention, which all belong to the protection scope of the present invention. Therefore, the protection scope of the present patent invention should be subject to the appended claims.

What is claimed is:

1. A decorative sheet, wherein comprising:
a supporting body including a first surface and a second surface opposite to the first surface;
a solid state thin film located on the first surface of the supporting body, wherein the solid film has a thickness of no more than 1 μm.

2. The decorative sheet according to claim 1, wherein a material of the solid film is one or more of an elementary substance, a metal oxide, a non-metal oxide or an organic material.

3. The decorative sheet according to claim 1, wherein a bonding layer is provided between the supporting body and the solid film.

4. The decorative sheet according to claim 1, wherein the supporting body is one or a combination of two or more of PET, PMMA, PC, a heat-curing adhesive, a light-curing adhesive, organic glass or inorganic glass.

5. An electronic device cover plate, wherein comprising:
a housing including a user plane and an inner surface opposite to the user plane;
a bonding layer located on the inner surface of the housing;
a solid film located on a side of the bonding layer away from the housing;
a coloring layer located on a side of the solid film away from the bonding layer.

6. The electronic device cover plate according to claim 5, wherein the solid film has a thickness of no more than 0.8 μm.

7. The electronic device cover plate according to claim 5, wherein the housing is made of inorganic glass, a composite plate or organic glass.

8. An electronic device cover plate, wherein comprising:
a housing including a user plane and an inner surface opposite to the user plane;
a decorative sheet including a supporting body and a solid film, the supporting body including a first surface and a second surface opposite to the first surface, the solid film located on the first surface of the supporting body;
a bonding layer located between the housing and the decorative sheet, the solid film in the decorative sheet facing towards the bonding layer.

9. The electronic device cover plate according to claim 8, wherein the housing is made of inorganic glass, a composite plate or organic glass.

10. The electronic device cover plate according to claim 8, wherein the cover plate is also provided with a coloring layer, the cover plate being located on the second surface of the supporting body; and/or
the coloring layer being located between the supporting body and the solid film.
